(19) United States
(12) Patent Application Publication
(10) Pub. No.: US 2009/0039478 A1
(43) Pub. Date: Feb. 12, 2009

(54) Method For Utilizing Heavily Doped Silicon Feedstock To Produce Substrates For Photovoltaic Applications By Dopant Compensation During Crystal Growth

(76) Inventors: Charles E. Bucher, Venetia, PA (US); Daniel L. Meler, Norcross, GA (US); Dominic Leblanc, Becancour (CA); Rene Bolavart, Trois-Riviers (CA)

Correspondence Address: HOLLAND & KNIGHT LLP;ATTN: STEFAN V. STEIN/ IP DEPT., POST OFFICE BOX 1288, TAMPA, FL, 33601-1288, US

(21) Appl. No.: 12/044,887

(22) Filed: Mar. 7, 2008

Related U.S. Application Data
(63) Continuation-in-part of application No. 11/684,599, filed on Mar. 10, 2007.
(60) Provisional application No. 61/016,049, filed on Dec. 21, 2007.

(51) Int. Cl. H01L 29/06; H01L 21/66

(52) U.S. Cl. 257/655; 438/10; 257/E29.005; 257/E21.531

(57) ABSTRACT

A method for using relatively low-cost silicon with low metal impurity concentration by adding a measured amount of dopant and or dopants before and/or during silicon crystal growth so as to nearly balance, or compensate, the p-type and n-type dopants in the crystal, thereby controlling the net doping concentration within an acceptable range for manufacturing high efficiency solar cells.

### CROSS-REFERENCE TO RELATED APPLICATIONS

This application is a continuation-in-part patent application of non-provisional patent application Ser. No. 11/684,599 filed Mar. 10, 2007 and claims the benefit of provisional patent application 61/016,049, filed Dec. 21, 2007, the disclosure of each of which is hereby incorporated by reference herein.

### BACKGROUND OF THE INVENTION

1. Field of the Invention

This invention relates to the manufacture of photovoltaic solar cells. More particularly, this invention relates to methods for utilizing heavily doped silicon feedstock to produce substrates for photovoltaic applications by dopant compensation during crystal growth.

2. Description of the Background Art

Photovoltaic (PV) devices for producing electrical energy directly from sunlight have become increasingly popular in recent years. Worldwide production of PV cells in 2005 exceeded 1,500 MW, with power output determined under standard test conditions (1 kW/m² light intensity, Air Mass 1.5 Global spectrum, and cell at 25° C.). With these solar cells typically encased in a module having a selling price of approximately $5/W, the 1,500 MW production represents a $7.5B/year industry. Furthermore, the worldwide industry output, measured in MW/year, has a compounded annual growth rate in excess of 30%. Silicon solar cells comprise more than 90% of the market.

The starting silicon wafer represents over half the cost of a completed silicon solar cell. This high cost is not due to the unavailability of silicon, since silicon is the second most abundant element in the earth's crust, behind only oxygen. Rather, it is due to the high cost of purifying silicon to a level required for semiconductor applications, including PV, which is typically in the parts-per-billion (ppb) range. It is particularly important to have high purity levels of silicon with respect to transition metals (e.g., iron, titanium, vanadium, molybdenum, tungsten). It is equally important to have high purity levels of silicon with respect to atoms from Group III (e.g., boron, aluminum, gallium) and Group V (e.g., phosphorus, arsenic) in the Periodic Table of the Elements which serve as p-type and n-type dopants, respectively, in silicon. Some silicon purification processes are quite effective in reducing the concentration of transition metals to an acceptable level, but are not sufficiently effective in reducing the dopant atoms to an acceptable level.

It is an object of this invention to provide an improvement which overcomes the aforementioned inadequacies of the prior art methods for purifying silicon and provides an improvement which is a significant contribution to the advancement of the art of manufacturing solar cells.

Another object of this invention is to provide a method for using relatively low-cost silicon with low metal impurity concentration but contains a high dopant impurity concentration for solar cell substrates.

Another object of this invention is to provide a method for using relatively low-cost silicon with low metal impurity concentration by adding a measured amount of dopant (e.g., one or more p-type or n-type dopants), before and/or during silicon crystal growth so as to nearly balance, or compensate, the p-type and n-type dopants in the crystal, thereby controlling the net doping concentration within an acceptable range for manufacturing high efficiency solar cells.

Another object of this invention is to provide a method for compensating silicon feedstock having a dopant concentration to produce solar grade silicon, comprising the steps of calculating an initial compensating dopant based upon the dopant concentration to produce a desired resistivity, adding the initial compensating dopant to the silicon feedstock and then melting and directionally solidifying the silicon feedstock to achieve the desired resistivity over at least a portion of an ingot produced from the silicon feedstock.

Another object of this invention is to provide a method for compensating silicon feedstock having a dopant concentration to produce solar grade silicon, comprising the steps of calculating an initial compensating p-type dopant or dopants based upon the dopant concentration to produce a desired resistivity, adding the initial compensating p-type dopant or dopants (e.g., gallium or a gallium alloy) to the silicon feedstock, or during melting of the feedstock, and then directionally solidifying the silicon feedstock to achieve the desired resistivity over a substantial portion of an ingot produced from the silicon feedstock, thereby increasing the yield.

Another object of this invention is to provide a method for compensating silicon to produce solar grade silicon for solar cells, comprising the steps of analyzing the silicon feedstock for elements that behave as p type dopants or n type dopants and determining their initial concentrations; based upon the initial concentrations the p type dopants and n type dopants, calculating the necessary amount of compensating dopant required to achieve a desired resistivity range over at least a portion of the solar grade silicon; adding the compensating dopant to the silicon feedstock; and melting and directionally solidify said feedstock to achieve the desired resistivity over at least a portion of the solar grade silicon.

Another object of this invention is to provide a method for compensating excessively doped silicon while in a melt, comprising the steps of: (1) adding an initial amount of compensating dopant to the excessively doped silicon while in the melt to initially compensate the excessively doped silicon in the melt to an approximate initially-compensated resistivity; (2) sampling the initially compensated doped silicon while in the melt to measure its initially-compensated resistivity; (3) computing a second amount of compensating dopant needed to added to the initially compensated doped silicon while in the melt to compensate the initially-compensated silicon in the melt to an approximate second-compensated resistivity; and (4) adding the second amount of compensating dopant to the initially compensated silicon in the melt.

Another object of this invention is to provide a method for compensating silicon to produce solar grade silicon, comprising the steps of: analyzing the silicon feedstock for dopant concentrations, calculating the necessary compensating dopant required to produce the desired resistivity during directional solidification, and melting said feedstock and adding the compensating dopant during directional solidification to achieve the desired resistivity.

Another object of this invention is to provide a method for compensating silicon to produce solar grade silicon, comprising the steps of: analyzing the silicon feedstock for dopant concentrations; calculating the necessary compensating dopant required to produce the desired resistivity during directional solidification; and melting said feedstock and adding the compensating dopant during directional solidification to permit flipping from n type to p type and to preclude return flipping from p type to n type, or visa versa.

Another object of this invention is to provide a silicon in the form of a silicon ingot, sheet, a silicon ribbon or a silicon wafer for solar cells manufactured in accordance with one of the methods of the invention.

Another object of this invention is to provide a silicon in the form of a silicon ingot, sheet, a silicon ribbon or a silicon wafer for solar cells comprising both p and n type dopant whereby the difference between the p and n type dopants results in a resistivity between about 0.1 and 10 ohm-cm or more preferably between about 0.5 and 3 ohm-cm.

The foregoing has outlined some of the pertinent objects of the invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

For the purpose of summarizing this invention, this invention comprises methods for utilizing heavily doped silicon feedstock to produce substrates for photovoltaic applications by dopant compensation during crystal growth.

By way of background, compensation dopants impact the material properties of the silicon substrate including the minority carrier lifetime and diffusion constant. The most important material property for solar cells is lifetime, which is the average time that a photogenerated electron remains free (in the conduction band) before it returns to a bound state (in the valence band) by recombining with a hole. It is within this lifetime period that the electron must be collected by the internal action of the solar cell in order for the electron to contribute to the flow of electrical current from the cell.

Lifetime is determined by the rate at which photogenerated electrons and holes recombine, as described by the Shockley-Read-Hall (SRH) expression. (See, for example, D. L. Meier, J. M. Hwang, and R. B. Campbell, “The Effect of Doping Density and Injection Level on Minority Carrier Lifetime as Applied to Bifacial Dendritic Web Silicon Solar Cells,” IEEE Transactions on Electron Devices, volume ED-35, pages 70-79, 1988.) This recombination rate depends only on net doping concentration, not on total doping concentration. This means, for example, that a silicon wafer with a given level of structural and chemical defects will have the same excess (photogenerated) carrier lifetime whether the p-type doping level is 1×10¹⁶ B/cm³ (single dopant) or 10×10¹⁶ B/cm³ and 9×10¹⁶ P/cm³ (compensating p-type and n-type dopants), with a net p-type doping density of 1×10¹⁶ cm⁻³ and a total doping density of 19×10¹⁶ cm⁻³. Thus, the SRH expression shows there is no lifetime penalty associated with compensated silicon relative to uncompensated silicon for the same net doping density. In addition, the SRH expression also shows that lifetime generally increases as the net doping density decreases. Improved lifetime can therefore be achieved in accordance with this invention by partially compensating heavily-doped silicon in order to reduce the net doping density.

The second important material property of the silicon substrate is the diffusion constant for photogenerated minority carriers. The diffusion constant is important because minority carriers must, during their lifetime, move by diffusion from where they are created within the silicon wafer to (typically) the front region of the solar cell. There, the built-in electric field associated with the p-n junction collects the minority carriers. A high diffusion constant is desirable so the minority carriers can move quickly to the collecting region. Unlike lifetime, the diffusion constant may be determined by the total doping concentration rather than the net doping concentration.

In compensated silicon, all dopant impurity atoms are ionized (donor ions have a positive charge and acceptor ions have a negative charge), so that carriers (electrons and holes) are scattered by all dopants. Thus, some penalty is paid in solar cell efficiency for having compensated silicon rather than uncompensated silicon. (Efficiency is defined as the ratio of electrical power out of the cell to light power incident on the cell.)

For example, if silicon is doped p-type to 1 ohm-cm (typical of current multicrystalline silicon cell technology) using only boron as the dopant (1.43×10¹⁶ B/cm³), the diffusion constant for minority carrier electrons is 31.3 cm²/s. If, on the other hand, silicon is doped p-type to 1 ohm-cm by compensating a high concentration of boron (14.30×10¹⁶ B/cm³) with a somewhat lower concentration of phosphorus (12.87×10¹⁶ P/cm³), the diffusion constant for electrons is reduced to 13.8 cm²/s. If a lifetime of 15 μs is assumed, the electron diffusion length for uncompensated 1 ohm-cm silicon is 217 μm, while the diffusion length for compensated 1 ohm-cm silicon is 144 μm, where diffusion length is given by (diffusion constant×lifetime)^{1/2}. For this example, the efficiency calculated by finite element model PC ID is 14.0% for the uncompensated silicon (J_{SC} of 30.6 mA/cm² and V_{OC} of 0.605 V) while the efficiency calculated for the compensated silicon is 13.4% (J_{SC} of 29.6 mA/cm² and V_{OC} of 0.595 V). Thus, the approximate efficiency penalty for compensated silicon, coming not from lifetime but from diffusion constant, is approximately 0.6% (absolute) where the majority doping concentration is 10 times the net doping concentration. Of course, in cases where the majority doping is less than 10 times the net doping, the efficiency penalty is less. In an extreme case where the majority doping compensation is 100 times the net doping concentration, the diffusion constant for electrons is reduced to 7.2 cm²/s and the efficiency is calculated to be 12.8% (J_{SC} of 28.6 mA/cm² and V_{OC} of 0.587 V). The efficiency penalty is then 1.2% (absolute) using the same assumptions as above (net p-type doping of 1.43×10¹⁶ B/cm³, lifetime of 15 μs).

It is noted that since compensated silicon involves (nearly) balancing the concentration of one dopant type against the opposite type, there is a practical limit to how closely this balancing can be achieved. A net doping concentration that is 10% of the majority doping concentration is possible. Obtaining a net doping that is 1% of the majority doping may be achieved only with difficulty.

As supported by the theoretical expectations for lifetime and diffusion constant in compensated silicon described above, good solar cell performance can be obtained using silicon feedstock containing multiple dopant impurities.

For example, in accordance with the present invention, silicon ingots may be prepared with aluminum levels in the range 0.04-0.10 ppma, boron levels in the range 0.5-2.5 ppma, and phosphorus levels in the range 0.2-2.0 ppma as determined by mass spectroscopy (R. K. Dawless, R. L. Troup, and D. L. Meier, “Production of Extreme-Purity Aluminum and Silicon by Fractional Crystallization Processing,” Journal of Crystal Growth, volume 89, pages 68-74, 1988). When such silicon is used as a feedstock to produce dendritic web crystals for solar cell substrates, resistivities from below 0.17 Ω-cm up to 3.5 Ω-cm may be obtained. It is believed that in most cases the crystals would be p-type, but in some cases they would be n-type, depending on the relative concentration of p-type and n-type dopants in the feedstock and on their respective segregation coefficients. Expected Solar cell efficiencies range from 8.3% to 14.6%. Accordingly, good quality cells (14.6%) can be obtained from crystals with compensating dopants (primarily boron and phosphorus). Even without controlling the compensation in order to achieve a desired net doping, p-type and n-type dopants in the crystal would nearly balance to give relatively high resistivity (0.86 Ω-cm) leading to cells with respectable efficiency. Accordingly, the manufacturing method of present invention utilizes a controlled dopant compensation to produce crystals from which good quality solar cells can be fabricated consistently.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a fuller understanding of the nature and objects of the invention, reference should be had to the following detailed description taken in connection with the accompanying drawings in which:

Graph 1 is a graph showing the dopant distribution in the ingot having an initial feedstock concentration of 0.5 ppmw boron and 1.5 ppmw phosphorus;

Graph 2 is a graph showing the amount of p-type silicon determined by the [P]/[B] ratio and the amount of usable p-type silicon for the production of solar cells;

Graph 3 is a graph showing dopant distribution in the ingot having an initial feedstock concentration of 0.5 ppmw boron, 1.5 ppmw phosphorus and 25 ppmw gallium;

FIG. 1 represents feedstock with an excessive amount of boron in which none of the ingot would be acceptable because the (calculated) net doping is too high (>3.0×10¹⁶ cm⁻³);

FIG. 2 depicts simple compensation of boron with phosphorus prior to melting silicon in which the lower 57% of the ingot is calculated to fall within the acceptable range of resistivity;

FIG. 3 depicts the initial compensation with phosphorus prior to melting plus multiple dopant adjustments with boron during growth in which the lower 91% of the ingot is calculated to fall within the acceptable range of resistivity;

FIG. 4 depicts sampling the melt during growth and for adding compensating dopant;

FIG. 5 depicts, for Example 1, the calculated net doping concentration for directionally solidified system (DSS) ingot 060206-2 with initial melt concentrations of 5.1×10¹⁷ cm⁻³ for boron and 5.8×10¹⁷ cm⁻³ for phosphorus;

FIG. 6 illustrates a typical DSS ingot (265 kg), on which the bricks, wafers, and cell of Example 1, are positioned;

FIG. 7 depicts the measured efficiency of cells of Example 1, with cells ordered according to their open-circuit voltage values and showing a sharp spike of five cells at approximately 13% efficiency, believed to be from p-type wafers with low net doping cut from the ingot just before the type flips from p to n (i.e., near the 80% point of FIG. 5);

FIG. 8 depicts the measured short-circuit current of cells from Brick D3 of Ingot 060206-2 of Example 1, with cells ordered according to their open-circuit voltage values, showing the spike in short-circuit current for the relatively high efficiency cells resulting from the relatively high excess carrier lifetime for low net doping concentration;

FIG. 9 depicts the measured open-circuit voltage of cells from Brick D3 of Ingot 060206-2 of Example 1, with cells ordered according to their open-circuit voltage values (the highest value of open-circuit voltage being 0.623 V, with the five high efficiency cells having values ranging from 0.584 V to 0.593 V);

FIG. 10 depicts, for Example 2, the calculated net doping concentration for simulated feedstock having boron at 0.5 ppmw (6.5×10¹⁶ cm⁻³) and an initial compensation with arsenic showing the desired p-type net doping below 3×10¹⁶ cm⁻³ for 78% of the ingot;

FIG. 11 is a photograph of silicon Brick B2 from Ingot 060802-1 of Example 2 with initial dopant compensation showing 85% of the brick is p-type;

FIG. 12 depicts, for Example 2, the efficiency of cells fabricated from compensated ingot with Cell # in order from the bottom of the ingot to the top and showing the drop in efficiency about Cell #150 corresponding to the transition from p-type to n-type in the brick;

FIG. 13 depicts, for Example 2, the short circuit current density of cells fabricated from compensated ingot with Cell # in order from the bottom of the ingot to the top and showing the drop in current density about Cell #150 corresponding to the transition from p-type to n-type in the brick;

FIG. 14 illustrates the sample of silicon melt of Example 3 drawn into a quartz tube (left) and a section of silicon removed from tube (right) for measurement from which the resistivity and type of the silicon section were determined to provide information on the net dopant concentration in the melt;

Chart 1 is a chart modeling the result of net doping concentration in the crystal without gallium dopant addition;

Chart 2 is a chart modeling the result of net doping concentration in the crystal with gallium dopant addition;

Table 1 is a table showing the measured type, resistivity and lifetime of the bricks from Example 2; and

Table 2 is a table showing the measured type, resistivity and lifetime of the bricks from Example 3.

### DETAILED DESCRIPTION OF THE PREFERRED EMBODIMENT

In accordance with the present invention, the distribution of dopants within a crystal is first calculated (if not already known). More specifically, solar cells in commercial production often are made from p-type silicon substrates with resistivity varying from 0.5 Ω-cm to 5 Ω-cm, corresponding to net acceptor concentrations ranging from 3.04×10¹⁶ cm⁻³ to 2.70×10¹⁵ cm⁻³. By way of example, a silicon feedstock having a high boron dopant concentration of 1.14×10¹⁷ cm⁻³ may be used to produce a silicon ingot by the directional solidification process. Since the segregation coefficient (ratio of concentration in the solid to concentration in the liquid) is 0.80 for boron, the doping density of boron in the first silicon to grow would be 9.12×10¹⁶ cm⁻³, or three times the desired amount. Because boron accumulates in the melt during directional solidification, the boron concentration in the crystal would become even larger as the crystal grows. The concentration of boron in the solid silicon would be calculated by the Scheil equation (E. Scheil, Z. Metallkd., volume 34, page 70, 1942) which assumes perfect stirring in the molten liquid and no diffusion of boron in the solid:

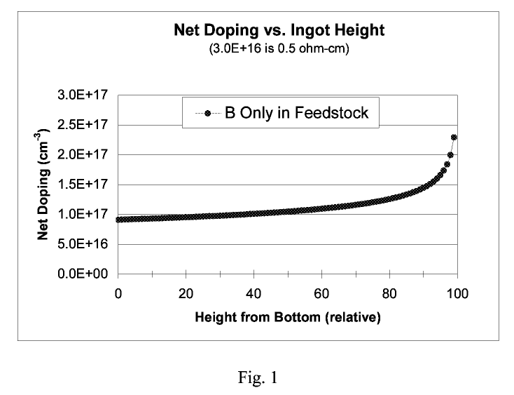

Cₛ(fₛ)=kC₀(1−fₛ)^{(k-1)} (1)

where C_{S} is the concentration of boron in the solid silicon, k is the segregation coefficient of boron, C₀ is the concentration of boron in the initial melt, and f_{S} is the fraction of the total mass of silicon that has solidified. FIG. 1, which represents feedstock with an excessive amount of boron, is a plot of C_{S} calculated as a function of f_{S} with C₀ of 1.14×10¹⁷ cm⁻³ and k of 0.80. Note that at the beginning of the ingot, C_{S} is 9.12×10¹⁶ cm⁻³ and increases from that value to approximately 2.29×10¹⁷ cm⁻³near the end of the ingot. Since the boron concentration in the silicon crystal would always be greater than the maximum desired value of 3.04×10¹⁶ cm⁻³, none of this ingot would be suitable for solar cell wafers because the (calculated) net doping is too high (>3.0×10¹⁶ cm⁻³ ).

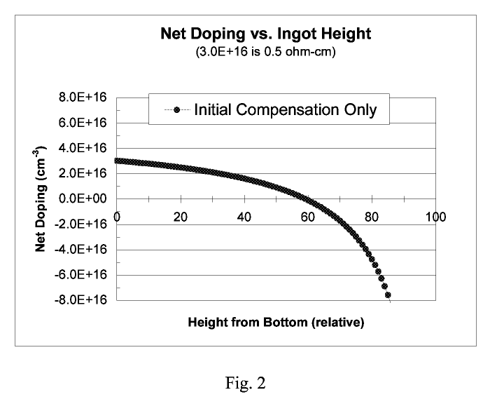

However, as shown in FIG. 2, if phosphorus is added as a compensating dopant to the initial melt (i.e., adding phosphorus atoms at a concentration of 1.74×10¹⁷ cm⁻³ to the initial melt), then the net doping concentration in the crystal (boron concentration—phosphorus concentration) can be brought into the desired range over most of the crystal (specifically, calculation indicates that the lower 57% of the ingot falls within the acceptable range of resistivity). Phosphorus has a segregation coefficient (k) of 0.35, and so tends to accumulate in the melt to a greater extent than boron which has a segregation coefficient of 0.80. The result is that at some point the crystal turns from p-type (positive net doping where boron dominates) to n-type (negative net doping where phosphorus dominates), as shown in FIG. 2. As noted in this specific example, for the first 57% of the crystal, the net doping density is within the desired range of 3.04×10¹⁶ cm⁻³ to 2.70×10¹⁵ cm⁻³ with the boron concentration exceeding the phosphorus concentration. Because both boron and phosphorus are present in the crystal at a concentration far below the concentration of silicon atoms (5.0×10²² cm⁻³), the two types of impurity atoms are incorporated into the silicon crystal independently according to their segregation coefficients. That is, boron and phosphorus are assumed to follow Eq. 1 individually, each without regard to the presence of the other in the melt.

In practice, the dopant concentration(s) in the starting silicon feedstock may be determined by an analytical technique, such as glow discharge mass spectroscopy (GDMS) or inductively coupled plasma mass spectroscopy (ICPMS), and a suitable amount of dopant to be added to the starting charge may be calculated so as to make the majority of the crystal suitable for solar cell substrates. Usually the dopant would be added in the form of very low resistivity (0.002-0.005 Ω-cm) silicon pieces. This method for achieving the desired net doping concentration may be termed “Initial Compensation Only”, since a single adjustment to the doping in the feedstock would be made in the starting silicon charge prior to melting the silicon and no adjustment would be made during crystal growth. This would suggest an accurate assay of the silicon feedstock (e.g., by GDMS or ICPMS) so that the amount of dopant present in the feedstock would be known and the required amount of compensating dopant could be calculated to bring most of the silicon crystal into an acceptable range. Although applicable to any number of dopants in the silicon feedstock, boron, gallium and phosphorous dopants are preferred since they are available in significant quantity. It is noted that this approach is simple in that the growth hardware and the growth process for directional solidification need not necessarily be changed. However, it does suggest that the assay of the silicon feedstock be representative of the whole charge, and also be sufficiently accurate and precise to allow a calculation of the amount of dopant to be added in the initial compensation.

Assuming the primary dopants are boron and phosphorous, to summarize the proportion of the p-type silicon in the melt (See Graph 1):

Condition: [P]_{ppma,s} =[B]_{ppma,s} (p-n junction)
$\frac{{[ P ]}_{ppmw}}{{[ B ]}_{ppmw}} = \frac{30.974}{10.811} \times \frac{0.80 \cdot {( 1 - fs )}^{0.80 - 1}}{0.35 \cdot {( 1 - fs )}^{0.35 - 1}}$

| Quantity of p-type | [P]/[B] ratio |
|---|---|
| (% of the ingot) | (ppmw/ppmw) |
| 0 | 6.55 |
| 80 | 3.17 |
| 90 | 2.32 |
| 95 | 1.70 |
| 99 | 0.82 |

The dopant concentrations in usable compensated of p-type silicon may be summarized as follows:

Resistivity criteria: 0.5 Ω·cm to 3 Ω·cm

NCC (Net current carrier)

NCC=[B]_{ppma,s}−[P]_{ppma,s}

To obtain 0.5 Ω·cm min., NCC≦3.3×10¹⁶ a/cm³

To obtain 3 Ω·cm max., NCC≦4.6×10¹⁵ a/cm³

$$N C C \leq 3.3 \times {10}^{16} \frac{a}{{cm}^{3}} \cdot \frac{1 {cm}^{3}}{2.33 g} \cdot \frac{28.0855 g}{6.02 \times {10}^{23} a} \cdot 1000000 = 0.66 ppma$$

$$N C C \geq 4.6 \times {10}^{15} \frac{a}{{cm}^{3}} \cdot \frac{1 {cm}^{3}}{2.33 g} \cdot \frac{28.0855 g}{6.02 \times {10}^{23} a} \cdot 1000000 = 0.09 ppma$$

$$0.09 ppma \geq N C C \geq 0.66 ppma$$

From these calculations, a more preferred range of boron and phosphorus to make solar cells is:

a. ppmw<Boron (ppmw)<1 ppmw

b. ppmw<Phosphorus (ppmw)<2.5 ppmw

From the forgoing, as represented in Graph 2, starting with a known level in boron and phosphorus, the average chemistry of the melt of silicon may be adjusted by adding boron or phosphorus and/or diluting with poly-silicon (silicon at 99.9999999% Si purity) to get the most quantity of p-type material having a resistivity of 0.5 to 3 Ω·cm in the ingot.

Is it noted that the upgraded metallurgical silicon may be diluted at different ratios with poly-silicon (i.e. silicon produced by the Siemens process) to be in the best area of the graph. This action does not change the phosphorus to boron ratio. This ratio can be modified by adding small amounts of phosphorus or boron.

In accordance with one aspect of the present invention, the quantity of usable p-type silicon may be increased by adding another p-type compensating dopant (other than boron); for example:

| p-type | Distribution | |
|---|---|---|
| dopant | coefficient | Atomic weight |
| Al | 2 × 10⁻³ | 26.98 |
| Zn | 1 × 10⁻⁵ | 65.37 |
| Ga | 8 × 10⁻³ | 69.72 |
| In | 4 × 10⁻⁴ | 114.82 |

These p-type compensating dopants increase the proportion of usable p-type silicon after the multi-crystalline solidification of the ingot. It is noted that gallium (Ga) and aluminum (Al), which have a high value of distribution coefficient, have a very good compensation effect at the end of the crystallization to compensate for the rapid increase in the phosphorus concentration.

The amount of aluminum (Al) or gallium (Ga) to add to the silicon melt is preferably:

0ppmw<Gallium (ppmw)<250 ppmw

$$0 ppmw < Aluminum ( ppmw ) < 100 ppmw$$

$$N C C = {[ B ]}_{ppma , s} + {[ Ga ]}_{ppma , s} - {{[ P ]}_{ppma , s} \\ [ Ga ]}_{ppma} = {[ Ga ]}_{ppmw} \times \frac{28.0855}{69.723} = {[ Ga ]}_{ppmw} \times 0.403$$

$${k}_{Ga} = {0.008 \\ [ Ga ]}_{ppma , s} = 0.008 \cdot {[ Ga ]}_{ppma , o} \cdot {( 1 - {f}_{s} )}^{0.008 - 1}$$

It is further noted that producers of solar cells would prefer to keep the addition of boron to a minimum level due to a phenomenon called “light induced degradation” (i.e., the initial rapid light-induced degradation of cell performance). As reflected in Graph 3 compared with Graph 1, the use of gallium, which has a better stability than boron, as the compensating dopant of a silicon feedstock having a high phosphorus to boron ratio, would be preferred over boron, to increase the proportion of usable ingot in the production of solar cells.

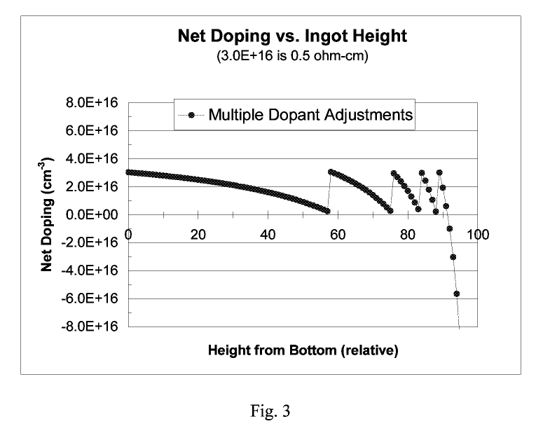

In accordance with another aspect of the present invention, compensating dopant or dopants may be added into the crystal growth period itself to substantially increase the fraction of the ingot which has net doping in the desired range. More specifically, as shown in FIG. 3, if four additional dopant adjustments are made during solidification, the fraction of crystal that would suitable for solar cell wafers may be increased from 57% associated with initial compensation only to 91% with initial compensation plus compensation during growth. Preferably, the amount of dopant that must be added in a typical production-scale directional solidification is initially calculated.

For example, taking a starting charge of 265 kg of silicon feedstock doped with boron to 1.14×10¹⁷ cm⁻³, the initial compensation (prior to melting) may be calculated to require 4.2 kg of silicon doped to 0.005 Ω-cm with phosphorus. Following the initial compensation, silicon doped with boron to 0.004 Ω-cm may be added in the following amounts during growth: 160 g after 58% of the silicon is solidified, 92 g after 76% is solidified, 64 g after 84% solidified, and 54 g after 89% solidified, resulting in 91% of the ingot being usable.

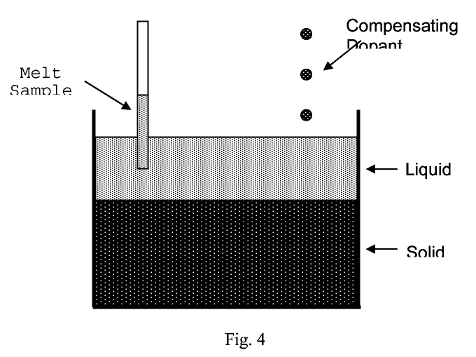

Although calculations such as the above may be made to determine the required additions of dopant to maintain the resistivity and type of the crystal in the desired range, a preferred approach in accordance with the present invention as shown in FIG. 4 is to sample the melt periodically to assess net doping in the melt, and to make adjustments accordingly. The melt may be sampled by drawing some molten silicon into a quartz tube where it solidifies. This melt sample may then be withdrawn from the furnace and the net dopant type assessed, e.g., by a hot probe type tester. The resistivity of the sample may alternatively be determined by direct electrical measurements (four point probe) or by a non-contact method using an induction coil pick up. Further alternatively, a mass spectroscopy analysis may be performed on the withdrawn sample to assess the quantity of different dopant species in the melt.

After sampling, the required compensating dopant may then added through a second port in the furnace as growth continues. This sampling and dopant addition preferably occurs without compromising the growth ambient which is usually an inert atmosphere (e.g., argon) under reduced pressure (below atmospheric). For example, the required isolation between the growth chamber and the melt sampling and dopant addition ports on the furnace may be achieved with a load-lock system.

It is noted that during the sampling, the height of the column of liquid silicon that is drawn up into the quartz tube may be controlled by the pressure difference between the furnace ambient and the interior of the quartz tube. For example, if the furnace ambient is maintained at 100 mbar and the interior of the quartz tube is evacuated with a vacuum pump, this pressure difference of 100 mbar would draw silicon in the quartz tube to a height of approximately 44 cm. The solidification of the silicon in the tube is preferably controlled so that the silicon at the top of the column solidifies first. Because of segregation of dopants in the silicon, this first-to-solidify in the sample column of silicon would mimic the dopant concentration in the large crystal. Thus, by measuring the resistivity and type of the topmost silicon in the sampling tube, the resistivity and type of silicon that is simultaneously freezing in the crystal may be determined. However, if it is desired to maintain the pressure of the ambient in the furnace at some relatively high value (e.g., 600 mbar), then the pressure in the sampling tube may be controlled to draw only a desired and manageable amount of silicon into the tube. For example, with an ambient pressure of 600 mbar, reducing the pressure in the tube to 500 mbar will also draw 44 cm of liquid silicon into the tube for analysis. In each of these techniques, a silicon sample may be obtained at any point during crystal solidification to represent the crystal at that time. Then, adjustments to the doping of the melt may accordingly be made in real time to maintain the net doping in the solidifying crystal within a desired range.

The mobility of the majority carriers may be measured (e.g., by the Hall effect) on the sample drawn from the melt. Mobility (μ) depends on the total dopant concentration and therefore it may be used as an indicator of that concentration over the range 10¹⁵ cm⁻³ to 10¹⁹ cm⁻³. Resistivity (ρ) depends on the concentration of majority carriers and the majority carrier mobility. For example, the resistivity (ρ) of a p-type sample is given as:

ρ=(qμₚp)⁻¹ (2)

where p is the concentration of holes, μp is the hole mobility, and q is the charge on the electron. A measurement of both ρ and μₚ may be used to determine p, the net doping concentration from Eq. 2. The total doping concentration may be determined from μₚ. With a knowledge of both total doping and net doping, the amount and type of dopant to be added to the melt to maintain net doping within a desired range may be calculated with some confidence, particularly if the dopant species are known (e.g., boron and phosphorus). It should be pointed out that determination of type and resistivity of the melt sample is adequate for making adjustments to the melt, but that the additional determination of majority carrier mobility enables more refined control since the net doping of Eq. 2 can then be determined more precisely.

In accordance with the present invention, continuous or semi-continuous feeding of the melt with compensating dopant may be employed, rather than the discrete additions of dopant as indicated in FIG. 3. If the dopant content (species and concentration) of the initial silicon charge is known fairly accurately and precisely, then the delivery of compensating dopant in a semi-continuous fashion may be calculated to narrow the range of the net doping. Of course, sampling the melt to confirm proper dopant content during such semi-continuous dopant compensation mode may still be conducted.

### EXAMPLES FOR IMPLEMENTING THE INVENTION

### Example 1

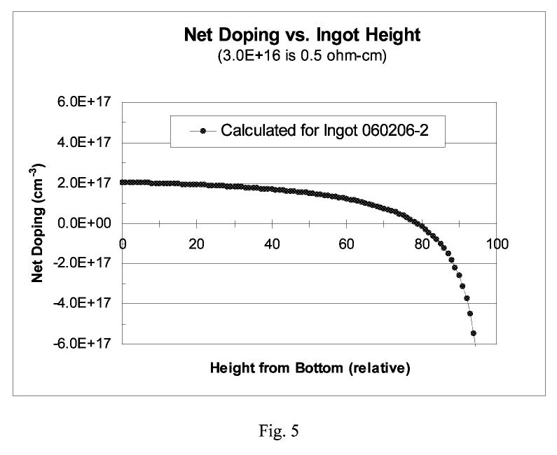

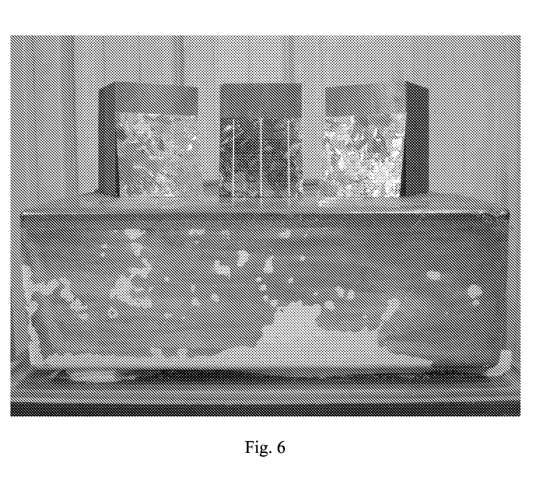

A candidate silicon feedstock, identified as “Brand A-6N,” was procured. A GDMS analysis indicated a very high concentration of boron and phosphorus, with boron at 4.6 ppmw (12.0 ppma or 6.0×10¹⁷ cm⁻³) and phosphorus at 15 ppmw (13.6 ppma or 6.8×10¹⁷ cm⁻³). Note that the boron concentration in the feedstock is 20 times the maximum value desired in the silicon crystal (3.0 ×10¹⁶ cm⁻³). Troublesome metals were generally below their respective GDMS detection limits, with V below 0.005 ppmw, Li, Ti, Mn, Co, Ni, Ag, and W all below 0.01 ppmw, S, Cu, Zn, Ga, As, Mo, Sb, and Pb all below 0.05 ppmw, and Cr below 0.1 ppmw. Only Fe and Al were detected at 0.06 ppmw and at 0.32 ppmw, respectively. A full-sized ingot (ID 060206-2), with a mass of 265 kg, was produced at Solar Power Industries in a DSS (directional solidification of silicon) furnace using 225 kg of the Brand A-6N feedstock and 40 kg of undoped silicon. FIG. 5 depicts the expected net doping in the ingot that was calculated using Eq. 1. The presence of boron and phosphorus in the feedstock was taken into consideration, along with the dilution of this feedstock with undoped silicon. Note that at the beginning of the ingot the net doping is more than six times the desired maximum of 3.0×10¹⁶ cm⁻³ and only in a small region around the cross-over point near 80% solidification are wafers expected to be p-type with resistivity less than 0.5 Ω-cm, as desired. As shown in FIG. 6, bricks were cut from the ingot, wafers were cut from the bricks, and cells (156 mm square, 270 μm thick) were made from the wafers.

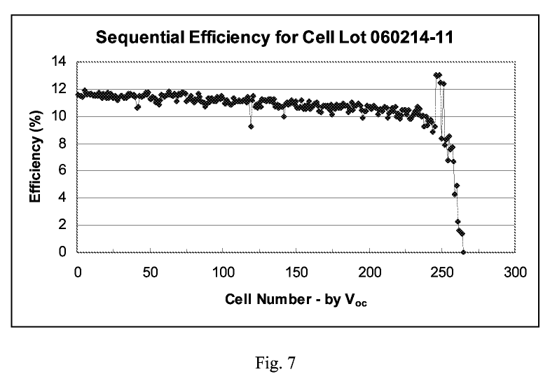

Wafers cut from Brick D3 of Ingot 060206-2 were processed into 156 mm square cells in Lot 060214-11. Efficiency values for the 265 cells produced from such brick are shown in FIG. 7, as measured under standard test conditions (1 kW/m², AM1.5, 25° C.). During the processing of these wafers and the measurement of the completed cells, no special effort was made to keep the wafers in the order that they were cut from the brick. Instead, for purposes of analysis, the cells were ordered according to their open-circuit voltage (V_{oc}) value, with cell 1 having the highest V_{OC} value and cell 275 having the lowest. Since V_{oc} normally decreases with decreasing net doping, this ordering would be expected to approximately reproduce the order of the wafers in the brick, beginning with cell 1 from the bottom of the brick.

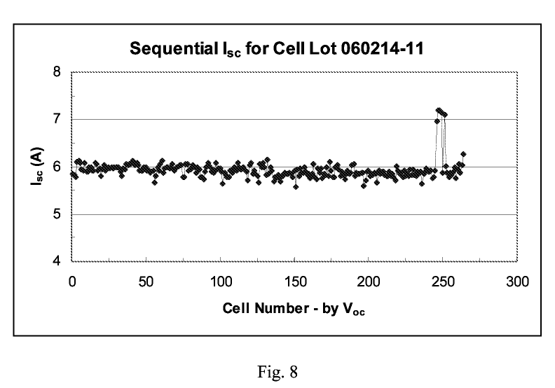

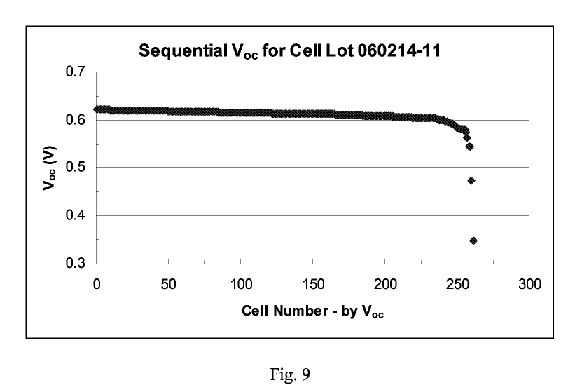

A noticeable feature of FIG. 7 is the cluster of five cells near cell number 250 having efficiency about 13%, significantly greater than the efficiency of other cells in the lot. These five cells are believed to be those having wafer resistivity in the range of 0.5 Ω-cm to 5 Ω-cm (net doping from 3.04×10¹⁶ cm⁻³ to 2.70×10¹⁵ cm⁻³)(i.e., wafers having a high boron concentration nearly compensated with phosphorus). As shown in FIG. 8, this is further supported by examining the short-circuit current of cells from Lot 060214-11. Again, near cell 250 there is a significant increase in the short-circuit current values for the high efficiency cells. As shown in FIG. 8, since short-circuit current is most strongly related to excess carrier lifetime, the lifetime in the nearly compensated wafers would be considerably higher than lifetime in wafers with larger net doping concentration. In fact, it is this larger value of short-circuit current that allows the cells to reach a high efficiency level of 13%. The five high efficiency cells have open-circuit voltage values ranging from 0.584 V to 0.593 V, also consistent with wafer resistivity in the desired range. As shown in FIG. 9, the most efficient cell had an efficiency of 13.1%, with J_{sc} of 29.6 mA/cm², V_{oc} of 0.591 V, and FF of 0.748.

The benefits observed in Ingot 060206-2 of this Example 1 indicate the value of controlled dopant compensation. Even with the very high concentrations of boron and phosphorus in feedstock Brand A-6N, some 13% cells were obtained. With controlled dopant compensation, done either initially before melting or with multiple dopant adjustments during growth, market-worthy cells may be produced in spite of a very high concentration of dopants in the silicon feedstock. Similar results were also obtained for cells from Brick D2 of Ingot 060206-2, thereby indicating that the effects which were observed and described above are reproducible.

### Example 2

In order to demonstrate the benefits of dopant compensation in a controlled manner, a full-sized (265 kg) silicon ingot was produced using intrinsic silicon with boron added at a concentration of 0.5 ppmw (6.5×10¹⁶ B/cm³). This represented silicon feedstock which had a residual boron content at a level which may be obtained by some low-cost purification processes. With a segregation coefficient of 0.80, the expected boron concentration at the beginning (bottom) of a directionally-solidified ingot is 5.2×10¹⁶ B/cm³. This is almost twice the maximum level of 3.0×10¹⁶ B/cm³ desired in a substrate for solar cells, and which would increase as the crystal grows as the melt becomes more highly concentrated in boron. To bring the net doping concentration into the desired range for this simulated impure feedstock, the excess boron was compensated with arsenic in the initial silicon charge. The purpose was to demonstrate that feedstock that has a higher-than-desired dopant impurity concentration may be compensated into a desired doping range and that solar cells of good efficiency may be made in spite of the compensating dopants.

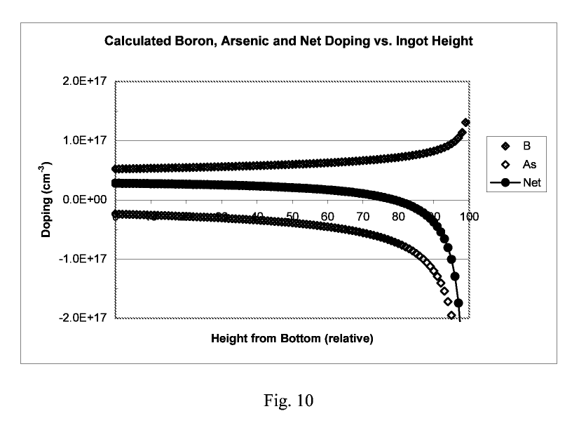

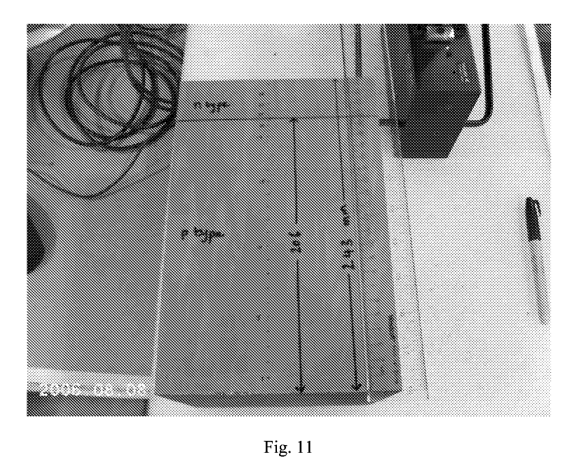

Analysis based on Eq. 1 indicated that arsenic at a concentration of 8.0×10¹⁶ As/cm³ should be added to the initial charge in order to create an ingot which is p-type with net doping below 3.0×10¹⁶ cm⁻³ over as much of the ingot as possible. The results of the analysis are given in FIG. 10 which shows the concentration of boron and arsenic in the ingot as a function of ingot height, along with the net doping concentration. Note that with the addition of arsenic the brick goes from being unacceptable over its entire height because of the high concentration of boron to being acceptable over 78% of its height.

Ingot 060802-1 of Example 2 was grown by directional solidification under the conditions given above. Sixteen bricks were cut from the ingot, each nominally 156 mm×156 mm×240 mm. FIG. 11 is a photograph of Brick B2. A clear demarcation between the lower p-type section of the brick and the upper n-type section was indicated by hot-probe type testing. Specifically, 85% of the height of the brick (206 mm/243 mm) was p-type, in approximate agreement with the 78% expected from the calculation. The resistivity was measured on the face of the brick and ranged from approximately 0.7 Ω-cm at the bottom to approximately 8 Ω-cm at the end of the p-type region.

Wafers were cut from Brick B2 with a nominal thickness of 240 μm. Type and resistivity were measured for the wafers after saw damage was removed by a KOH etch. Excess carrier lifetime was measured by the quasi-steady state photoconductivity decay (QSSPCD) technique after the wafer surfaces were passivated by a phosphorus diffusion having a sheet resistance of approximately 40 ΩD/□ to give an n⁺pn⁺ or an n⁺nn⁺ structure. Results are given in Table 1 for wafers from the bottom of the brick to the top.

Note in Table 1 that the measured wafer resistivities are consistent with the calculated net doping curve of FIG. 10. Note also that the measured lifetimes tend to increase with resistivity and that lifetimes for the n-type wafers are typically greater than those for p-type wafers.

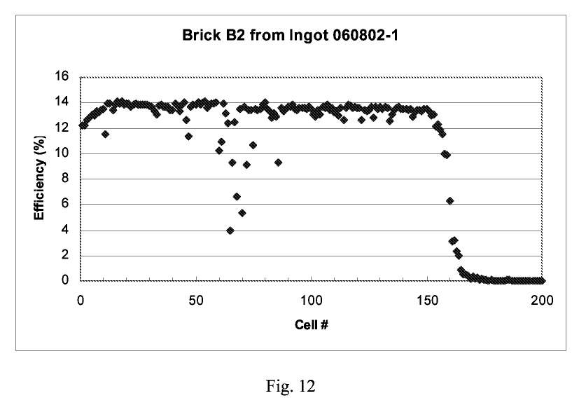

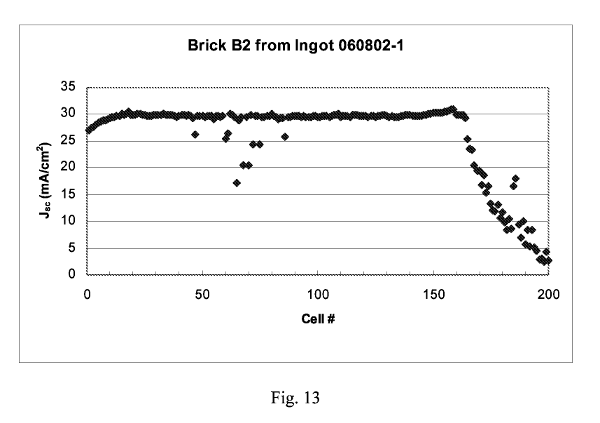

Solar cells, 156 mm square, were fabricated from the wafers cut from Brick B2 in cell processing lot 060809-9. The measured efficiencies of cells from the bottom of the brick to the top are depicted in FIG. 12. Over the p-type section of the brick, the cell efficiency was nearly constant at approximately 14%. Since the solar cell process are designed for p-type wafers, the cell efficiency falls off dramatically for the n-type wafers in the upper section of the brick. Over the p-type section, cells had a median efficiency of 13.5%, with short-circuit current of 7.22 A, open-circuit voltage of 0.604 V, and fill factor of 0.754. These parameter values are all respectable for production multicrystalline solar cells. The highest efficiency was 14.1%, with short-circuit current of 7.21 A, open-circuit voltage of 0.613 V, and fill factor of 0.776. A plot of short circuit current density for these compensated cells is depicted in FIG. 13. Note the correlation of this current density with measured lifetime for cells made from p-type wafers. The reduced efficiency and short circuit current observed for cells from near the bottom of the ingot (approximately the first 15 cells) was likely associated with impurities coming from the crucible material itself (fused silica) or from the crucible coating (silicon nitride). (The crucible holds the molten silicon.) The slight increase in short circuit current density for cells near the end of the p-type region (near cell 160) is believed to be associated with the relatively high resistivity of those wafers.

For comparison, cells were also made from wafers cut from Ingot 060501-1 which had the same quality of intrinsic silicon as Ingot 060802-1, but doped only with boron to a resistivity of approximately 2 Ω-cm with no compensating n-type dopant. These cells had a median efficiency of 13.8%, with short-circuit current of 7.52 A, open-circuit voltage of 0.598 V, and fill factor of 0.746. The highest efficiency was 14.5%. Note that cells from the compensated ingot had median efficiency 0.3% (absolute) lower than the median efficiency for cells from the uncompensated ingot. This difference was consistent with the efficiency penalty for compensated silicon associated with reduced minority carrier diffusion constant described earlier.

### Example 3

In order to demonstrate the benefits of gallium dopant for N-Type silicon feedstock, a full-sized (265 kg) multi-crystalline silicon ingot was produced: 90.60 kg of N-Type silicon was charged with 174.40 kg prime semiconductor grade poly silicon raw material. The initial dopant concentration included 0.41 ppmw boron (5.74×10¹⁶ B/cm³) and 1.15 ppmw phosphorus (5.23×10¹⁶ P/cm³). Since gallium is a P-Type material, higher N-Type dopant concentration was required for testing purpose. Another 1.85 ppmw phosphorus (8.37×10¹⁶ P/cm³) in highly-doped wafers (0.002 Ωcm) shape was added to make the final charging silicon feedstock with 3.0 ppmw phosphorus (1.36×10¹⁷ P/cm³) of concentration.

For comparison, Chart 1 shows the net doping concentration from the bottom to the top of the ingot (boron concentration—phosphorus concentration) if the silicon ingot was cast without any other dopant addition. The entire ingot would be N-Type which would not be suitable for a substrate for solar cells.

Gallium has a segregation coefficient (k) of 0.008, which is very small compared to boron (0.8) and phosphorus (0.35), and tends to accumulate in the melt to a much greater extent. Therefore, to compensate for this N-Type dopant concentration, 109.25 ppmw (2.20×10¹⁸ Ga/cm³) of gallium was doped in the form of pure gallium (99.99999%) pellets shape. More specifically, as shown in Chart 2, with the addition of gallium, the net doping concentration in the crystal (boron concentration+gallium concentration−phosphorus concentration) is brought into the desired range over most of the crystal (>80%). The top 15% was cropped due to the impurity concentration and low resistivity. The charge was molten and cast into a multi-crystalline ingot, 080107-3, in a production DSS (Directional Solidification System) furnace.

The ingot was cut into 16 bricks on the Squarer saw following the standard ingot cutting procedure. One center brick, B2, one corner brick, D1, two side bricks, B1 and B4, were tested for excess carrier lifetime, N/P-Type, and resistivity. The testing was performed on the face of the bricks. The resistivity ranged from ˜0.8 Ωcm from the bottom to ˜0.5 Ωcm on the top of the bricks. The entire ingot was P-Type which demonstrated a successful compensation of dopant concentration. The detailed results are shown in Table 2 (showing the measured brick resistivities being consistent with the calculated net doping curve of Chart 2).

Two bricks, B2 and D1, were etched in KOH bath to remove the saw damage on the surface. Wafers were cut from two bricks with a nominal 220 μm. Solar cells, 156 mm square, were fabricated from the wafers using standard solar cell processing as Lot # 080115-1. Cells had a median efficiency of 14.55%, with short-circuit current of 7.40 A, the open-circuit voltage of 0.605 V, and fill factor of 0.791. These parameter values are all respectable for production of multi-crystalline solar cells. The highest efficiency is 15.08%, with short-circuit current of 7.55 A, the open-circuit voltage of 0.61 V, and fill factor of 0.798.

### Example 4

Upgraded metallurgical silicon with initial dopant concentration of 1.5 ppmw of boron and 4.5 ppmw of phosphorus is melted with poly-silicon in a crystallization furnace. The ratio of UMG-Si to poly-Si is 1:2. The amount of p-type silicon having a resistivity in between 0.5 Ω□cm and 3 Ω□cm is approximately 79.6% of the ingot (an increase of 72% of ingot usage over similar example without poly-silicon).

### Example 5

Upgraded metallurgical silicon with initial dopant concentration of 0.5 ppmw of boron and 1.5 ppmw of phosphorus is melted in a crystallization furnace. The equivalent of approximately 25 ppmw of gallium is added to the melt and crystallization is carried out. The amount of p-type silicon having a resistivity in between 0.5 Ω□cm and 3 Ω□cm is approximately 96.8% of the ingot (an increase of 17% of ingot usage over similar example without gallium).

### Example 6

Upgraded metallurgical silicon with initial dopant concentration of 0.5 ppmw of boron and 2.5 ppmw of phosphorus is melted in a crystallization furnace. The equivalent of approximately 65 ppmw of gallium is added to the melt and crystallization is carried out. The amount of p-type silicon having a resistivity in between 0.5 Ω□cm and 3 Ω□cm is approximately 96.1% of the ingot (an increase of 62% of ingot usage over similar example without gallium).

### Example 7

Upgraded metallurgical silicon with initial dopant concentration of 0.4 ppmw of boron and 3.0 ppmw of phosphorus is melted in a crystallization furnace. The equivalent of approximately 109 ppmw of gallium is added to the melt and crystallization is carried out. The amount of p-type silicon having a resistivity in between 0.5 Ω□cm and 3 Ω□cm is approximately 91.4% of the ingot, an increase of 91% of ingot usage over similar example without gallium).

### Example 8

Upgraded metallurgical silicon with initial dopant concentration of 0.4 ppmw of boron and 3.0 ppmw of phosphorus is melted in a crystallization furnace. The equivalent of approximately 0.37 ppmw of boron is added to the melt and crystallization is carried out. The amount of p-type silicon having a resistivity in between 0.5 Ω□cm and 3 Ω□cm is approximately 65.0% of the ingot (a decrease of 26% of ingot usage over Example 7 above).

### Example 9

Dendritic web silicon ribbon crystals were grown in Run SPI-101-5. The dendritic web crystal growth technique was different from the directional solidification technique employed in the above Examples in that crystals are grown at atmospheric pressure rather than at reduced pressure, the melt volume was much smaller at 0.3 kg rather than 265 kg, crystals were single crystal ribbon that exit the growth chamber rather than a multicrystalline ingot which remained inside the growth chamber, and melt volume remained approximately constant during a crystal growth run rather than decreasing during the run. It is also noted that operation at atmospheric pressure facilitated adding dopant to the melt and also sampling the melt.

The dendritic web growth run started with a 335 g melt to which 2.3×10¹⁹ boron atoms were added via silicon doped with boron to 0.0045 Ω-cm. The dendritic web crystal grown from this melt was measured to be p-type with a resistivity of 0.18 Ω-cm. This resistivity was less than the minimum of 0.5 Ω-cm desired for solar cell substrates. Consequently, the melt was compensated by adding arsenic (n-type dopant) after the melt was replenished with intrinsic silicon to replace the silicon removed from the melt in the form of the crystal. A total of 3.8×10¹⁹ arsenic atoms were added via silicon doped with arsenic to 0.0028 Ω-cm. A dendritic web crystal grown after this addition of arsenic to compensate the boron was measured to be p-type with a resistivity of 6.9 Ω-cm. Thus, the resistivity was raised above the minimum level of 0.5 Ω-cm, as desired.

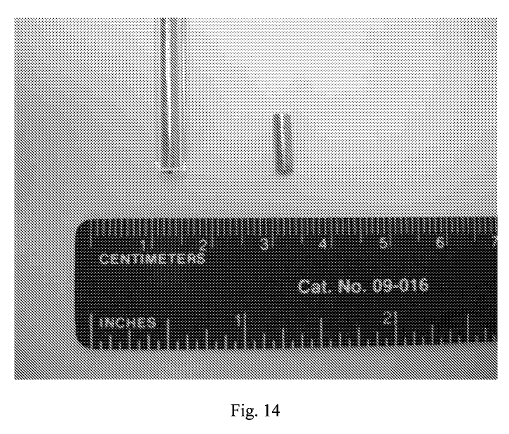

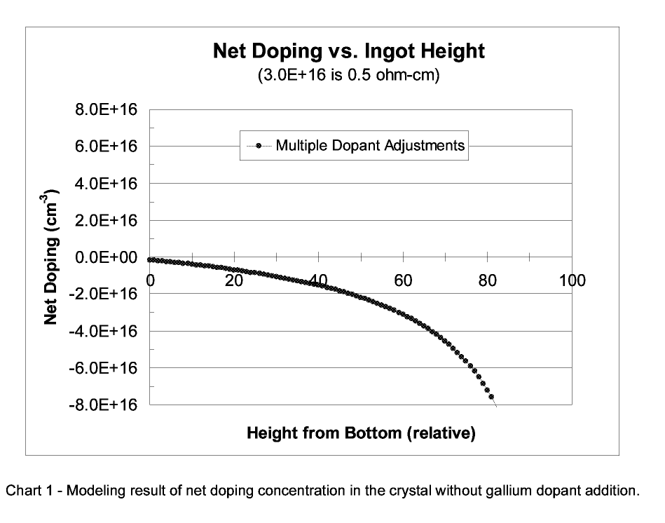

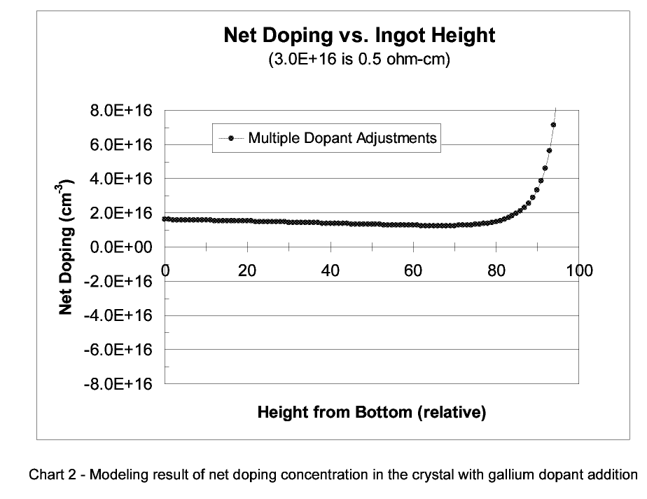

The melt was sampled by inserting a quartz tube into the melt and drawing some molten silicon into the tube with the aid of a vacuum pump. The silicon sample was allowed to cool and solidify in the quartz tube, and the tube was then withdrawn from the furnace. The quartz tube with silicon sample inside is shown in FIG. 14 along with a slug of silicon that was removed from the tube for measurement. The silicon slug had a length of 0.962 cm and a diameter of 0.292 cm. From a hot-probe type tester, it was determined to be n-type. Also, a four-point probe measurement was used to measure its resistivity of 0.31 Ω-cm. Consequently, the slug had a higher concentration of arsenic than boron, as expected for a melt from which 6.9 Ω-cm, p-type crystals were grown, given that the segregation coefficient for boron is 0.80 and for arsenic is 0.30.

The dendritic web crystal growth of Example 3 demonstrates that the resistivity and type of a silicon crystal may be adjusted during a crystal growth run to an acceptable value (>0.5 Ω-cm, p-type) by adding compensating dopant to the melt and that the melt may be sampled by drawing molten silicon into a quartz tube, then testing the solidified sample to determine net dopant type and resistivity.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

Now that the invention has been described,

TABLE 1
Measured type, resistivity, and
lifetime for wafers cut from Brick B2 from
Ingot 060802-1. Wafers are listed in order
from bottom to top of brick.

| | Resistivity | Lifetime |
|---|---|---|
| Type | (Ω-cm) | (μs) |
| P | 0.64 | 4.2 |
| P | 0.69 | |
| P | 0.68 | |
| P | 0.67 | 4.6 |
| P | 0.82 | |
| P | 0.80 | |
| P | 0.83 | 6.8 |
| P | 0.86 | |
| P | 0.81 | |
| P | 0.89 | 7.8 |
| P | 0.90 | |
| P | 0.90 | 8.7 |
| P | 1.03 | 6.2 |
| P | 0.95 | |
| p | 0.86 | |
| p | 0.89 | |
| P | 0.88 | 8.0 |
| P | 0.95 | |
| P | 0.75 | 7.8 |
| P | 0.95 | |
| P | 0.71 | |
| P | 0.88 | 7.1 |
| P | 0.92 | |
| P | 0.95 | |
| P | 1.02 | 5.9 |
| P | 0.98 | |
| P | 1.07 | |
| P | 1.17 | 6.3 |
| P | 1.18 | |
| P | 1.41 | |
| P | 1.15 | 7.0 |
| P | 1.42 | |
| P | 1.50 | |
| P | 1.61 | 6.1 |
| P | 1.81 | |
| P | 2.04 | |
| P | 2.02 | 7.9 |
| P | 2.23 | |
| P | 1.89 | |
| P | 2.83 | 10.6 |
| P | 3.52 | 13.0 |
| P | 6.70 | 16.5 |
| N | 403.61 | 36.0 |
| N | 14.75 | 47.5 |
| N | 3.15 | 25.1 |
| N | 1.83 | 16.8 |
| N | 0.86 | |
| N | 0.49 | |
| N | 0.30 | 9.8 |
| N | 0.30 | |

TABLE 2
Measured type, resistivity, and lifetime for bricks, B2, D1, B1, and B4 from gallium
doped ingot, 080107-3.

| | Bottom | P-type | | | | | | | | | | | | | Top |
|---|---|---|---|---|---|---|---|---|---|---|---|---|---|---|---|
| B2 | 0.88 Ωcm | 0.89 | 0.85 | 0.89 | 0.88 | 0.89 | 0.90 | 0.91 | 0.90 | 0.91 | 0.90 | 0.90 | 0.89 | 0.88 | 0.84 |
| | 0.46 μs | 4.02 | 4.61 | 4.32 | 3.75 | 2.33 | 2.33 | 2.03 | 1.90 | 1.79 | 1.59 | 1.29 | 1.27 | 1.06 | 0.40 |
| D1 | 0.75 Ωcm | 0.75 | 0.77 | 0.77 | 0.77 | 0.77 | 0.78 | 0.79 | 0.81 | 0.82 | 0.84 | 0.88 | 0.86 | 0.83 | 0.61 |
| | 0.20 μs | 0.20 | 1.00 | 1.58 | 0.53 | 0.95 | 0.35 | 0.28 | 0.25 | 0.18 | 0.21 | 0.30 | 0.64 | 0.79 | 0.94 |
| B1 | 0.60 Ωcm | 0.68 | 0.80 | 0.72 | 0.93 | 0.78 | 0.74 | 0.80 | 0.89 | 0.72 | 0.76 | 0.90 | 0.87 | 0.80 | 0.85 |
| | 1.49 μs | 1.19 | 2.83 | 4.29 | 3.78 | 3.13 | 2.84 | 2.61 | 2.18 | 1.95 | 1.95 | 1.79 | 1.35 | 1.26 | 0.99 |
| B4 | 0.71 Ωcm | 0.96 | 1.09 | 1.06 | 1.02 | 0.72 | 0.85 | 0.89 | 0.94 | 0.97 | 1.00 | 1.04 | 0.89 | 0.72 | 0.47 |
| | 0.32 μs | 1.99 | 4.69 | 4.86 | 4.22 | 2.94 | 2.73 | 2.55 | 2.32 | 2.12 | 1.97 | 1.58 | 1.35 | 0.76 | 0.59 |

What is claimed is:

1. A method for compensating silicon feedstock having a dopant concentration to: produce solar grade silicon, comprising the steps of:
calculating an initial compensating dopant based upon the dopant concentration to produce a desired resistivity.
adding the initial compensating dopant to the silicon feedstock.
melting and directionally solidifying the silicon feedstock to achieve the desired resistivity over at least a portion of an ingot produced from the silicon feedstock.

2. The method as set forth in claim 1, further comprising the step of analyzing the dopant concentration prior to calculating the initial compensating dopant and then calculating the initial compensating dopant based upon the analyzed dopant concentration to produce the desired resistivity.

3. The method as set forth in claim 2, wherein the step of analyzing the dopant concentration employs glow discharge mass spectroscopy.

4. The method as set forth in claim 2, wherein the step of analyzing the dopant concentration employs inductively coupled plasma mass spectroscopy.

5. The method as set forth in claim 1, further comprises the steps of:
analyzing the melted silicon feedstock to determine the resistivity of the silicon in the melt;
adding a second compensating dopant based upon the dopant concentration in the melted silicon feedstock.

6. The method as set forth in claim 5, wherein said step of adding the second compensating dopant based upon the dopant concentration in the melted silicon feedstock comprises drawing a sample of the molten silicon from the melt and analyzing it to determine its net dopant type.

7. The method as set forth in claim 6, wherein the sample is drawn by a tube in which it solidifies.

8. The method as set forth in claim 7, wherein the sample solidifies in the tube from the top of the tube to the bottom of the tube.

9. The method as set forth in claim 7, wherein the sample is drawn by the tube by a pressure difference between an interior of the tube and a furnace containing the melted silicon feedstock.

10. The method as set forth in claim 6, wherein the sample is analyzed by a hot probe tester.

11. The method as set forth in claim 6, wherein the sample is analyzed to determine its resistivity.

12. The method as set forth in claim 11, wherein the resistivity of the sample is determined by direct electrical measurement.

13. The method as set forth in claim 11, wherein the resistivity of the sample is determined by an induction coil pick-up.

14. The method as set forth in claim 5, wherein the steps of analyzing the melted silicon feedstock to determine the resistivity of the silicon in the melt and adding a second compensating dopant based upon the dopant concentration in the melted silicon feedstock are repeated at least twice.

15. The method as set forth in claim 5, wherein the second compensating dopant comprises pelleted or powdered dopant.

16. The method as set forth in claim 5, wherein the step of analyzing the melted silicon feedstock and the step of adding the second compensating dopant occurs while maintaining the melted silicon feedstock at an inert atmosphere under reduced pressure.

17. The method as set forth in claim 1, wherein the initial compensating dopant comprises a p-type dopant and if necessary a n-type dopant.

18. The method as set forth in claim 17, where the initial p-type compensating dopant comprises one or more of B, Al, Ga, In or Tl.

19. A method for compensating silicon to produce solar grade silicon for solar cells, comprising the steps of:
analyzing the silicon feedstock for elements that behave as p type dopants or n type dopants and determining their initial concentrations;
based upon the initial concentrations the p type dopants and n type dopants, calculating the necessary amount of compensating dopant required to achieve a desired resistivity range over at least a portion of the solar grade silicon;
adding the compensating dopant to the silicon feedstock; and
melting and directionally solidify said feedstock to achieve the desired resistivity over at least a portion of the solar grade silicon.

20. The method as set forth in claim 19, wherein the desired resistivity range comprises a desired resistivity range of about 0.1 to 10 ohm-cm.

21. The method as set forth in claim 19, wherein the desired resistivity range comprises a desired resistivity range of about 0.4 to 4 ohm-cm.

22. The method as set forth in claim 19, wherein the desired resistivity range comprises a desired resistivity range of about 0.4 to 4 ohm-cm over about 30% or more of the solar grade silicon.

23. The method as set forth in claim 19, wherein the compensating dopant comprises a p-type dopant and if necessary a n-type dopant.

24. The method as set forth in claim 23, where the initial p-type compensating dopant comprises one or more of B, Al, Ga, In or Tl.

25. The method as set forth in claim 19, wherein the solar grade silicon comprises a silicon ingot.

26. The method as set forth in claim 19, wherein the solar grade silicon comprises a silicon sheet.

27. The method as set forth in claim 19, wherein the solar grade silicon comprises a silicon ribbon.

28. The method as set forth in claim 19, wherein the step of analyzing the silicon feedstock for elements that behave as p type dopants or n type dopants and determining their initial concentrations comprises determining their net differences and wherein the step of calculating the necessary amount of compensating dopant required to achieve a desired resistivity range over at least a portion of the solar grade silicon based upon the initial concentrations of the p type dopants and n type dopants comprises calculating the necessary amount of compensating dopant based up their net differences.

29. The method as set forth in claim 28, wherein the step of adding the compensating dopant to the silicon feedstock comprises adding p type compensating dopant.

30. A method for compensating excessively doped silicon while in a melt, comprising the steps of:
(1) adding an initial amount of compensating dopant to the excessively doped silicon while in the melt to initially compensate the excessively doped silicon in the melt to an approximate initially-compensated resistivity;
(2) sampling the initially compensated doped silicon while in the melt to measure its initially-compensated resistivity;
(3) computing a second amount of compensating dopant needed to added to the initially compensated doped silicon while in the melt to compensate the initially-compensated silicon in the melt to an approximate second-compensated resistivity; and
(4) adding the second amount of compensating dopant to the initially compensated silicon in the melt.

31. The method for compensating excessively doped silicon while in the melt as set forth in claim 30, comprising the steps of repeating steps (2), (3) and (4) at least once to sample the second compensated doped silicon while in the melt, to compute a third amount of compensating dopant needed to added to the second compensated doped silicon while in the melt to compensate the second compensated silicon in the melt to an approximate third compensated resistivity and adding the third amount of compensating dopant to the second compensated silicon in the melt.

32. The method for compensating excessively doped silicon while in the melt as set forth in claim 31, comprising the steps of repeating steps (2), (3) and (4) “N” number of times to sample the N−1 compensated doped silicon while in the melt, to compute an N amount of compensating dopant needed to added to the N−1 compensated doped silicon while in the melt to compensate the N−1 compensated silicon in the melt to an approximate N compensated resistivity and adding the N amount of compensating dopant to the N−1 compensated silicon in the melt.

33. The method for compensating excessively doped silicon while in the melt as set forth in claim 32, wherein silicon crystals are grown in the melt at atmospheric pressure.

34. The method for compensating excessively doped silicon while in the melt as set forth in claim 31, wherein the silicon crystals comprise single crystal ribbons.

35. The method for compensating excessively doped silicon while in the melt as set forth in claim 32, wherein the compensating steps comprise adding Group V elements to increase the resistivity of the silicon in the melt.

36. The method for compensating excessively doped silicon while in the melt as set forth in claim 32, wherein the compensating steps comprise adding Group III elements to decrease the resistivity of the silicon in the melt.

37. The method as set forth in claim 30, wherein the step of sampling to measure Ohm-cm resistivity comprises drawing molten silicon sample into a tube and allowing the sample to solidify in the tube, and measuring the resistivity of the sample.

38. The method as set forth in claim 30, further comprises the step of testing the sample to determine the net dopant type.

39. A method for compensating silicon to produce solar grade silicon, comprising the steps of:
analyzing the silicon feedstock for dopant concentrations
calculating the necessary compensating dopant required to produce the desired resistivity during directional solidification.
melting said feedstock and adding the compensating dopant during directional solidification to achieve the desired resistivity.

40. The method as set forth in claim 39, wherein the step of adding the compensating dopant during directional solidification to achieve the desired resistivity comprises adding continuously.

41. The method as set forth in claim 39, wherein the step of adding the compensating dopant during directional solidification to achieve the desired resistivity comprises adding periodically.

42. The method of claim 39, wherein the desired resistivity is in a range of about 0.1 to 10 ohm-cm.

43. A method for compensating silicon during directional solidification to produce solar grade silicon, comprising the steps of:
melting silicon feedstock;
sampling the molten silicon and analyzing it for dopant concentrations;
calculating the necessary compensating dopant required to produce the desired resistivity during directional solidification; and
adding the compensating dopant during directional solidification to achieve the desired resistivity.

44. The method as set forth in claim 43, wherein the step of adding the compensating dopant during directional solidification to achieve the desired resistivity comprises adding continuously.

45. The method as set forth in claim 43, wherein the step of adding the compensating dopant during directional solidification to achieve the desired resistivity comprises adding periodically.

46. A method for compensating silicon to produce solar grade silicon, comprising the steps of:
analyzing the silicon feedstock for dopant concentrations;
calculating the necessary compensating dopant required to produce the desired resistivity during directional solidification; and
melting said feedstock and adding the compensating dopant during directional solidification to prevent from flipping type.

47. A method for compensating silicon to produce solar grade silicon, comprising the steps of:
analyzing the silicon feedstock for dopant concentrations;
calculating the necessary compensating dopant required to produce the desired resistivity during directional solidification; and
melting said feedstock and adding the compensating dopant during directional solidification to permit flipping from n type to p type and to preclude return flipping from p type to n type, or visa versa.

48. Silicon in the form of one of a silicon ingot, sheet, a silicon ribbon or a silicon wafer for solar cells comprising both p and n type dopant whereby the difference between the p and n type dopants results in a resistivity between about 0.1 and 10 ohm-cm.

49. A method for compensating silicon feedstock having a dopant concentration to produce solar grade silicon, comprising the steps of:
calculating an initial compensating p-type dopant and an n-type dopant if necessary based upon the dopant concentration to produce a desired resistivity,
adding the initial compensating p-type dopant and if necessary n-type dopant either to the silicon feedstock or during melting of the silicon feedstock,
directionally solidifying the silicon feedstock to achieve the desired resistivity over a substantial portion of an ingot produced from the silicon feedstock.

50. The method as set forth in claim 49, wherein said substantial portion of the ingot comprises at least 80% of the ingot.

51. The method as set forth in claim 50, wherein said p-type dopant comprises gallium or a gallium alloy.

52. The method as set forth in claim 50, wherein said p-type dopant comprises aluminum or a aluminum alloy.

53. A method for compensating silicon feedstock having a dopant concentration of phosphorus and boron to produce solar grade silicon, comprising the steps of:
adding a p-type compensating dopant other than boron and an n-type dopant if necessary to either to the silicon feedstock or during melting of the silicon feedstock to achieve a desired resistivity; and
directionally solidifying the silicon feedstock to achieve the desired resistivity over a substantial portion of an ingot produced from the silicon feedstock.

54. The method as set forth in claim 53, wherein said substantial portion of the ingot comprises at least 80% of the ingot.

55. The method as set forth in claim 54, wherein said p-type dopant comprises gallium, a gallium alloy.

56. The method as set forth in claim 54, wherein said p-type dopant comprises aluminum or a aluminum alloy.
